(19) United States
(12) Patent Application Publication
(10) Pub. No.: US 2013/0049124 A1
(43) Pub. Date: Feb. 28, 2013

(54) MOSFET INTEGRATED CIRCUIT WITH IMPROVED SILICIDE THICKNESS UNIFORMITY AND METHODS FOR ITS MANUFACTURE

(71) Applicants: Clemens Fitz, Dresden (DE); Stephan Waidmann, Dresden (DE); Stefan Flachowsky, Dresden (DE); Peter Baars, Dresden (DE); Rainer Giedigkeit, Dresden (DE)

(72) Inventors: Clemens Fitz, Dresden (DE); Stephan Waidmann, Dresden (DE); Stefan Flachowsky, Dresden (DE); Peter Baars, Dresden (DE); Rainer Giedigkeit, Dresden (DE)

(73) Assignee: GLOBALFOUNDRIES Inc., Grand Cayman (KY)

(21) Appl. No.: 13/223,016

(22) Filed: Aug. 31, 2011

(51) Int. Cl. H01L 27/088; H01L 21/3205

(52) U.S. Cl. 257/368; 438/682; 257/E21.296; 257/E27.06

(57) ABSTRACT

An MOSFET device having a Silicide layer of uniform thickness and which is substantially free of “Spotty” NiSi-type holes, and methods for its fabrication, are provided. One such method involves simultaneously depositing a metal layer (e.g. Ni) over the active and open areas of a semiconductor substrate. The depth to which some or all of the metal is transferred into the substrate is determined by thermal budget. A rapid thermal annealing process is employed to produce a NiSi layer of a uniform thickness in both the active and open areas. Upon achieving a NiSi layer of a desired thickness, the excess metal is removed from the substrate surface.

### TECHNICAL FIELD

The present invention generally relates to MOSFET semiconductor devices and methods for their fabrication, and more particularly to improved methods for fabricating MOSFET devices with enhanced Silicide thickness uniformity.

### BACKGROUND

The transistor is the basic building block of all present day integrated circuit (IC) designs and devices. Fundamentally, a transistor is an electronic switch which includes a source region, a drain region electrically insulated from the source, and a control gate formed within a semiconductor substrate. A control voltage applied to the gate electrode selectively controls the flow of current between the source and drain electrodes, thereby controlling the binary (“on” and “off”) state of the device.

A common integrated circuit implementation involves interconnecting a large number of field effect transistors (FETs), typically metal oxide semiconductor field effect transistors (MOSFETs), resulting in a highly complex, three dimensional integrated circuit semiconductor device. The mechanical and electrical integrity of the CA-contacts associated with the source, drain, and gate electrodes of these transistors can significantly impact device performance and manufacturing yield.

Moreover, as the number and complexity of functions implemented in IC devices (such as microprocessors and memory devices) increases, more and more transistors must be incorporated into the underlying integrated circuit chip. Hence, the fabrication of such large scale integrated circuit devices presents a number of competing manufacturing and processing challenges.

Presently known methods of fabricating the drain, source, and/or gate extensions and associated contacts involve applying a thin layer of metal atoms (such as Ni) to the device surface, for example by chemical vapor deposition (CVD), plasma enhanced chemical vapor deposition (PECVD), or physical vapor deposition (PVD). A metal Silicide layer (e.g. nickel Silicide) is then formed on the substrate surface using a thermal migration process such as rapid thermal annealing (RTA).

It is desired to produce a continuous, homogeneous nickel Silicide layer which is of uniform thickness in both the active and open regions of the device. However, presently known methods (referred to herein as processes of record or POR) of growing nickel Silicide on pFET active areas do not reliably produce a continuous nickel Silicide layer, especially in the presence of SiGe.

In particular, it has been observed that holes, voids, or tunnels are present in the Silicide. This is referred to as “Spotty nickel Silicide” or “Spotty NiSi”. Spotty nickel Silicide is characterized by smaller holes in the range of 5-10 nm, and larger holes in the range of 50-100 nm.

This effect is not typically seen on n-active/poly and p-poly and, accordingly, Spotty nickel Silicide is believed to be related to the presence of SiGe, which is often used in the context of strain engineering and mobility enhancement in the pFET channel.

As initially formed, the nickel Silicide layer appears to be substantially homogeneous across the device surface; but under thermal load and strain buildup in Middle of Line (MOL) processes (such as the deposition and ultraviolet cure (UV-cure) of PECVD SiN layers), Spotty NiSi is formed. Spotty NiSi is particularly problematic in that it can significantly increase contact resistance due to reduced conductive cross sectional area in the vicinity of the holes or voids. Even worse, a local open circuit condition may result. In addition, contacts may shift position, drift, or punch through a NiSi hole, possibly even into the junction. These and other effects of Spotty NiSi adversely impact IC device performance and device manufacturing yield.

Accordingly, a need exists to provide methods for fabricating an integrated circuit having a NiSi layer which is substantially devoid of holes, particularly in the active regions of the device. Additionally, it is desirable to provide MOSFET ICs having a continuous Silicide layer in the presence of SiGe. A further need exists to provide IC devices and methods for fabricating IC devices having a Silicide layer which is free of voids in the vicinity of high aspect ratio (AR) structures and which is of uniform thickness across the device surface.

Furthermore, other desirable features and characteristics of the present invention will become apparent from the subsequent summary and detailed description of the invention and the appended claims, taken in conjunction with the accompanying drawings, brief description of the drawings, the foregoing technical field and this background of the invention.

### BRIEF SUMMARY

In accordance with one embodiment, a method for fabricating a MOSFET IC includes depositing a metal layer over the active and open regions of a silicon substrate, transferring a portion of the metal layer into the surface of the active and open regions to form a Silicide layer, controlling the depth of penetration of the Silicide layer to a uniform thickness by exposing the substrate to a predetermined elevated temperature for a predetermined period of time, leaving some excess metal on the surface of at least the open region, and removing the excess metal from the surface of the open region.

In accordance with a further embodiment, a method for fabricating a MOSFET device is provided that includes depositing a layer of Ni on a device substrate using a CVD or PVD process to produce an Ni layer having a thickness greater than the thickness of the NiSi layer subsequently produced in the open region of the device. A NiSi layer is grown using a thermal migration process to define the thickness of the resulting NiSi layer in the open region.

A further embodiment provides a method growing the NiSi layer using a rapid thermal annealing process. After the NiSi layer is grown to a desired thickness in the open region of the device, the excess or unreacted Ni is removed, for example using a Ni-strip process.

In accordance with a further embodiment, a method for fabricating a MOSFET IC is provided which includes depositing a Ni layer in the active region of a device substrate at a thickness which, upon subsequent rapid thermal annealing, produces a continuous Nickel Silicide layer in the active region. A further aspect provides that this Nickel Silicide layer is substantially devoid of Spotty NiSi-type holes.

In accordance with another embodiment, a MOSFET IC is provided that includes a Nickel Silicide layer that is substantially free of holes in the active regions of the device surface, including bulk silicon as well as SOI (silicon-on-insulator).

In accordance with yet another embodiment, a MOSFET device is provided which is fabricated by a process which includes the step of depositing a Ni layer in the active region of a device substrate at a thickness which, upon subsequent rapid thermal annealing, produces a continuous Nickel Silicide layer in the active region, which Nickel Silicide layer is substantially devoid of Spotty NiSi-type holes.

### BRIEF DESCRIPTION OF THE DRAWINGS

The present invention will hereinafter be described in conjunction with the following drawing figures, wherein like numerals denote like elements, and wherein:

FIGS. 1-4 illustrate, in cross sectional views, portions of various prior art MOSFET integrated circuit devices and fabrication methods;

FIGS. 5-7 illustrate, in cross sectional views, the formation of a Nickel Silicide layer on a semi-conductor substrate;

FIGS. 8-9 illustrate, in cross sectional views, spotty Nickel Silicide holes in the vicinity of dense patterned structures fabricated in accordance with presently known methods; and

FIGS. 10-12 illustrate, in cross sectional views, new and improved methods for depositing a Nickel Silicide layer on a semi-conductor substrate.

### DETAILED DESCRIPTION

The following detailed description is merely exemplary in nature and is not intended to limit the invention or the application and uses of the invention. Furthermore, the invention is not bound by any theory presented in the preceding background or the following detailed description.

A MOSFET integrated circuit (IC) having a Silicide layer of uniform thickness and which is substantially free of “Spotty” NiSi-type holes, and methods for its fabrication, are provided. One such method involves simultaneously depositing a metal layer (e.g. Ni) over the active and open areas of a semiconductor substrate. The depth to which some or all of the metal is transferred into the substrate is determined by thermal budget. A rapid thermal annealing process is employed to produce a Nickel Silicide layer of a uniform thickness in both the active and open areas. Upon achieving a Nickel Silicide layer of a desired thickness, the excess metal is removed from the substrate surface.

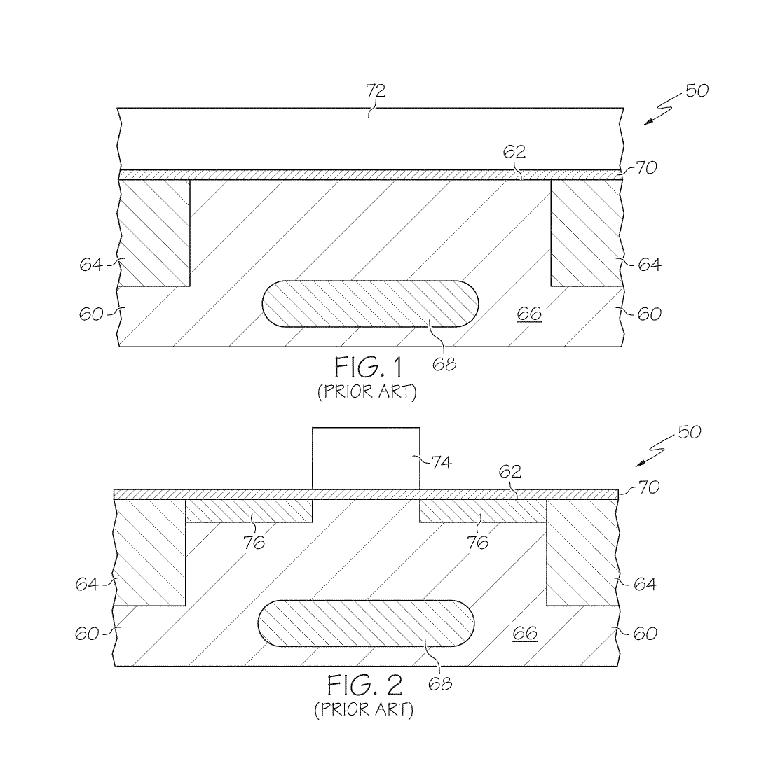

FIGS. 1-12 generally illustrate a portion of a MOSFET integrated circuit device 50 and various methods for its fabrication that avoid the problems with Spotty Nickel Silicide described above. The portion of IC device 50 that is illustrated is a single MOSFET transistor. In accordance with the various embodiments to be described, the single transistor can be either an n-channel MOS transistor or a p-channel transistor. The complete IC can include n-channel transistors, p-channel transistors, or can be a CMOS IC including both types. The described embodiments can be applied to any number of the transistors of the IC.

Various steps in the manufacture of MOSFET transistors are well known and, consequently, in the interest of brevity many conventional steps are mentioned only briefly herein or omitted entirely without providing the well known process details. Although the terms “MOS” and “MOSFET” device properly refer to a device having a metal gate electrode and an oxide gate insulator, as used herein these terms refer to any semiconductor device that includes a conductive gate electrode (whether metal or other conductive material) that is positioned over a gate insulator (whether oxide or other insulator) which, in turn, is positioned over a semiconductor substrate.

The method for fabricating IC device 50 in accordance with one embodiment of the invention may begin, as illustrated in FIG. 1, by providing a semiconductor substrate 60 having a surface 62. The semiconductor substrate can be silicon (Si), silicon admixed with germanium (SiGe), carbon, or other semiconductor material used in the semiconductor industry. Isolation regions 64 such as shallow trench isolation (STI) are formed in the semiconductor substrate, extend into the substrate from the surface, and serve to aid in defining a well region 66. Isolation regions 64 provide electrical isolation between a device (or devices) formed in well region 66, and devices formed in adjacent well regions. Although not used in all ICs, a buried layer 68 may be formed underlying the well region. For an n-channel MOS transistor the well region is impurity doped p-type.

In accordance with one embodiment the method of fabricating a semiconductor device continues by forming a thin insulating layer 70 on surface 62. A layer 72 of metal, silicon or dummy gate material such as polycrystalline silicon is deposited over the thin insulating layer.

As illustrated in FIG. 2, the method continues by patterning layer 72 to form a gate or other structure 74. Structure 74 can be formed by conventional photolithographic patterning and anisotropic etching, for example by reactive ion etching (RIE). In accordance with one embodiment source and drain extensions 76 are formed by ion implanting n-type conductivity determining ions such as arsenic ions into the surface of the well region using structure 74 as an ion implantation mask. The source and drain extensions are thus self aligned to structure 74.

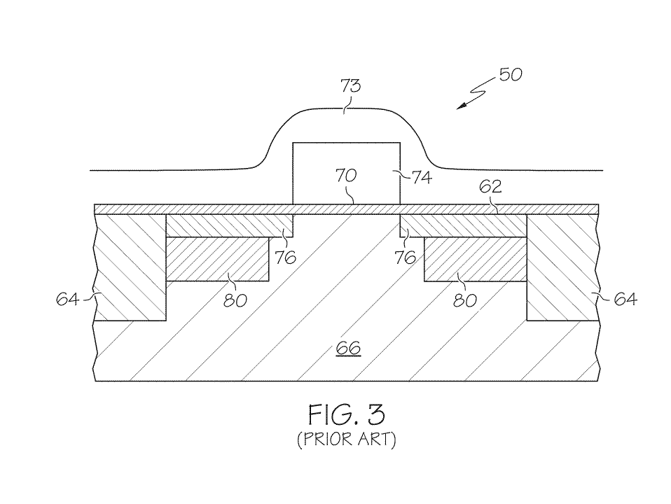

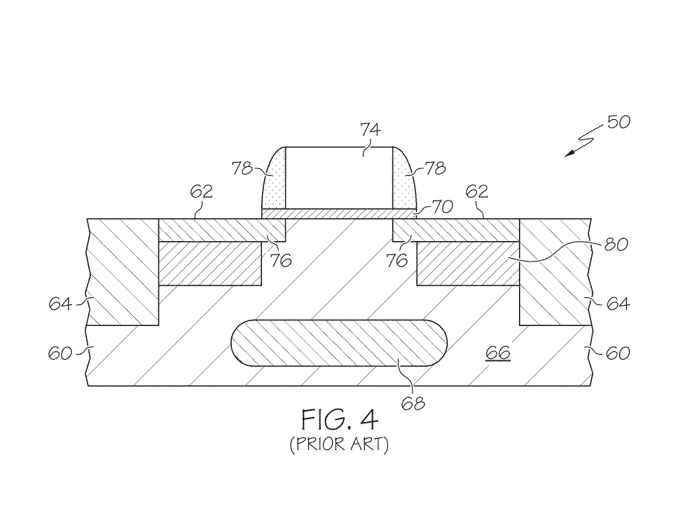

In accordance with one embodiment of the invention, sidewall spacers 78 are formed on the edges of structure 74 as illustrated in FIG. 3. The sidewall spacers can be formed, for example, by depositing a layer 73 of dielectric material such as an oxide or a nitride overlying structure 74 and insulating layer 70. The dielectric material is anisotropically etched with the anisotropic etching continuing to etch the exposed portion of thin insulating layer 70, to produce sidewall spacers 78 (see FIG. 4).

Referring to FIG. 4, deep source and drain regions 80 are formed by ion implanting n-type conductivity determining ions such as arsenic or phosphorous ions into the surface of well region 66 using structure 74 and sidewall spacers 78 as an ion implantation mask. The deep source and drain regions are thus self aligned to the sidewall spacers and also self aligned to and spaced apart from structure 74. The device structure is thermally annealed, for example by a rapid thermal annealing (RTA), to activate the implanted ions.

Although this description of the various embodiments is focused on the fabrication of an n-channel MOS transistor, those of skill in the art will understand that while the source and drain impurity doping process steps illustrated above have been carried out, a layer of masking material could be applied to cover and protect p-channel devices that may be part of the intended IC. After the n-type source and drain regions have been completed that masking layer could be removed and another masking layer applied to cover and protect the n-channel devices. The p-channel devices could then be processed in a manner similar to that described for the n-channel devices with an obvious change in impurity doping type. The thermal anneal to activate the implanted ions can be carried out either after each of the device types is implanted or after both of the device types receives the source and drain implants.

Referring now to FIGS. 4-7, in accordance with one embodiment of the invention, structure 74 suitably comprises a gate electrode 94, and layer 70 suitably comprises a gate insulator 92. Gate insulator 92 can be, for example, a layer of thermally grown silicon dioxide, perhaps admixed with nitrogen, overlaid by a layer of a hafnium oxide or other high k dielectric material. The composite gate insulator is a high k insulator as it has a dielectric greater than the dielectric constant of silicon dioxide alone. The gate electrode material can be, for example, a layer of metal overlaid by a layer of polycrystalline silicon. The layer of metal can be selected, as well known by those of skill in the art, to effect a proper threshold voltage for the MOSFET device being fabricated. In accordance with an alternate embodiment gate insulator layer 92 can be, for example, a layer of thermally grown silicon dioxide and gate electrode material 94 can be a layer of polycrystalline or amorphous silicon.

As will be well understood by those of skill in the art, device 50 can be further processed by conventional middle of line (MOL) and back end of line processing steps. Those processing steps may include, for example, etching contact openings through a layer of gap fill material to expose surface areas of the source and drain regions, forming silicide and/or metal contacts extending into the contact openings to the surfaces areas, forming conductive device interconnects, depositing interlayer dielectrics, and the like.

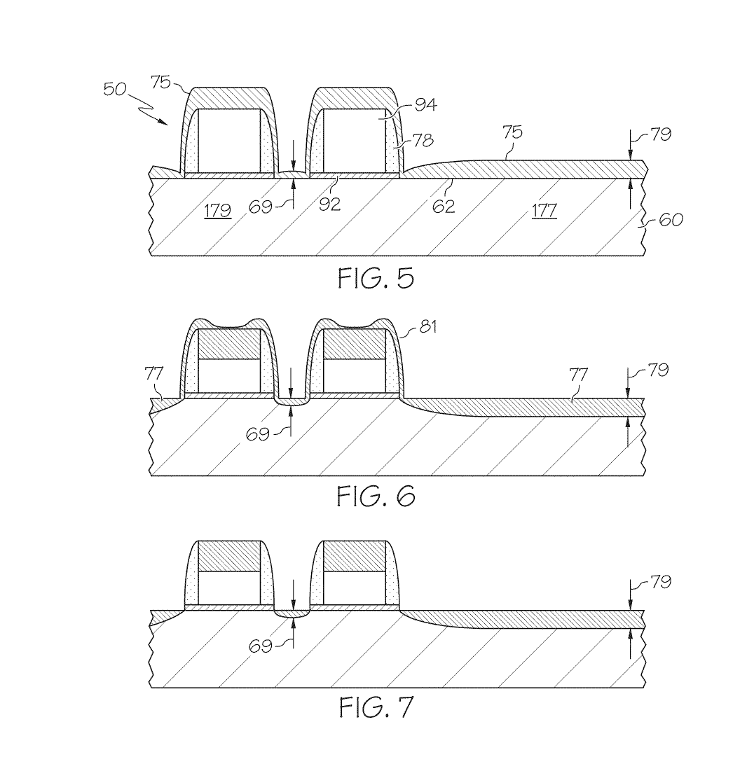

More particularly and with continued reference to FIGS. 5-6, in accordance with POR processes, a Nickel Silicide layer 77 is grown on surface 62 of substrate 60. Fabrication of silicide layer 77 involves the process of depositing a thin layer 75 of metal, for example Ni, over both an active region 179 as well as an open region 177 of substrate 60. Those skilled in the art will appreciate that active region 179 generally corresponds to dense patterned areas or regions containing high aspect ratio (AR) features. Conversely, open area 177 generally corresponds to areas with minimal or no features (e.g. gates, electrodes, or other microelectronic structures).

Also in accordance with POR processes, metallic layer 75 may be applied to surface 62 of substrate 60 as a thin layer of metal atoms (such as Ni), for example by chemical vapor deposition (CVD), plasma enhanced chemical vapor deposition (PECVD), or plasma vapor deposition (PVD). Metal layer 75 is typically in the range of 110 A Ni in POR processes.

With continued reference to FIGS. 5-6, metal layer 75 exhibits a first thickness 79 in open region 75, and a second thickness 69 in some areas of active region 79 due to, for example, the deep hole geometries associated with respective structures 50. Thickness 69 of layer 75 is typically less than thickness 79. This is in part because some of the metal is deposited on the side surfaces or sidewalls 78 of structures 94. This is particularly prevalent in hi aspect ratio (AR) features and structures, as well as in high density active regions.

With particular reference to FIG. 6, a patterned Nickel Silicide layer 77 is grown on the substrate surface using a thermal migration process such as rapid thermal annealing (RTA). In POR processes, annealing is conducted at 330 degrees Centigrade (330 C) for 30 seconds. This causes metal layer 75 to migrate into substrate 60 to an approximate depth 79 in open region 177, and to an approximate depth 69 in active region 179. Unreacted metal 81 may be removed using any suitable Ni-strip process.

It is desired to produce a continuous, homogeneous Nickel Silicide layer 77 which is of uniform thickness in both the active and open regions of the device. However, presently known methods of defining Nickel Silicide thickness on pFET active areas by PVD step coverage in conjunction with a thermal budget of 330 C for about 30 s result in a “Spotty” Nickel Silicide layer, especially in the presence of SiGe. Holes, voids, or tunnels are observed in the resulting Silicide characterized by smaller holes in the range of 5-10 nm, and larger holes in the range of 50-100 nm.

As initially grown, the Nickel Silicide appears to be substantially homogeneous across the device surface; but under thermal load and strain buildup in Middle of Line (MOL) processes (such as the deposition and ultraviolet cure (UV-cure) of PECVD SiN layers), Spotty Nickel Silicide is formed. Spotty Nickel Silicide is particularly problematic in that it can significantly increase contact resistance due to the reduced cross sectional area in the vicinity of the holes or voids. Even worse, a local open circuit condition may result. In addition, contacts may shift position, drift, or punch through a Nickel Silicide hole, possibly even into the junction. These and other effects of Spotty Nickel Silicide adversely impact IC device performance and device manufacturing yield.

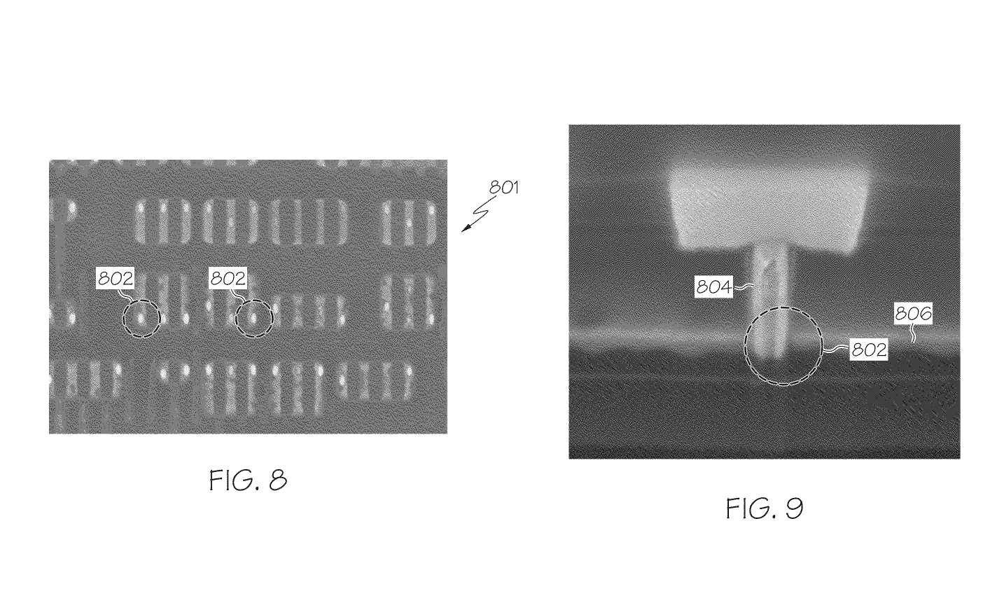

Referring now to FIGS. 8 and 9, dense patterned structures 801 fabricated in accordance with POR methods exhibit holes 802 in Nickel Silicide layer 806. As illustrated, a contact 804 may penetrate or even punch through hole 802. In POR processes, Spotty Nickel Silicide holes 802 are significantly more pronounced (for example on the order of 10:1 to 50:1 or greater) in dense patterned areas (source/drains) than in less densely patterned areas (open aresa) as a result of the thinner Nickel Silicide layer in active areas.

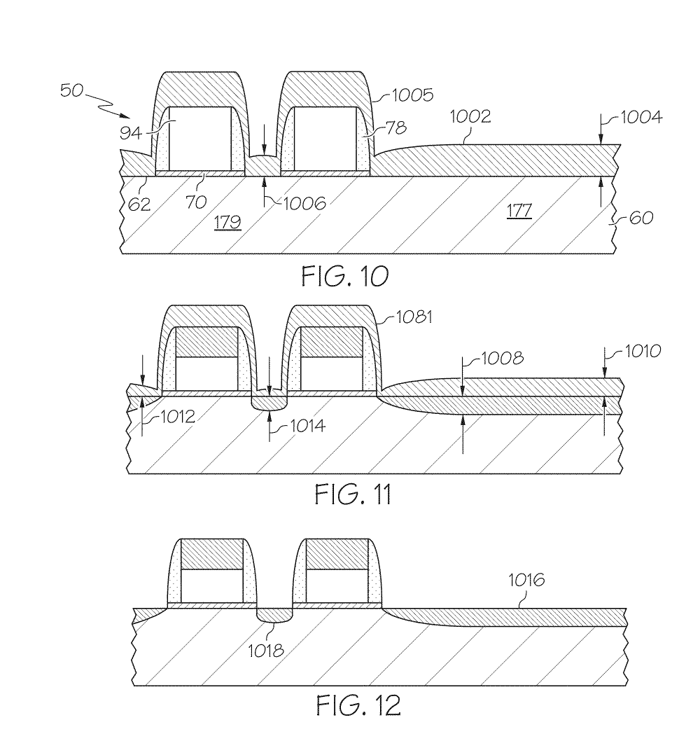

Referring now to FIGS. 10-12, IC devices 50 may be fabricated in accordance with a preferred embodiment by simultaneously applying a metal layer 1002 (e.g. Ni) to both the active and open areas of surface 62 of substrate 60 in the range of 200 A Ni (as opposed to 100 A Ni in the POR shown in FIG. 5). As discussed above in connection with FIGS. 5-7, the thickness 1004 of layer 1002 in open region 77 may be slightly greater than the thickness 1006 of layer 1002 in active area 79 due to the presence of microelectronic structures, particularly dense patterned and high AR structures.

That is, when metal is deposited in an active area, some of the metal is deposited on the top surfaces of microelectronic structures, and some of the metal is deposited on the substrate surface between microelectronic structures. Those skilled in the art will appreciate that some of the metal atoms which would otherwise fall on the substrate surface between structures may adhere to the side surfaces of the microelectronic structures and to their associated sidewalls (if any are present), resulting in a slightly thinner layer of metal between structures than observed in open areas.

In contrast to the POR process described above in FIGS. 5-7 wherein Nickel Silicide thickness was largely defined by PVD step coverage, in accordance with a preferred embodiment Nickel Silicide thickness is primarily controlled by thermal budget and, in particular, by annealing for about 30 seconds in the range of 240-320° C. (preferably about 280-300 and most preferably about 300 degrees C.). That is, the amount of metal which is transferred into the substrate from the top surface of the substrate (i.e., the thickness of the resulting annealed layer) is primarily determined by the thermal budget (time and temperature), as opposed to being determined by the initial thickness of the layer of metal to be transferred.

With continued reference to FIGS. 10-12, a thermal budget of 300 degrees C. for 30 seconds defines a Nickel Silicide layer portion 1016 having a thickness 1008 in open area 177 in the range of 50-200 A, and preferably about 100 A. However, because Nickel Silicide thickness is primarily thermally controlled according to a preferred embodiment, a Nickel Silicide layer 1018 in active area 179 has a thickness greater than that achieved in POR processes, thereby mitigating or eliminating the Spotty Nickel Silicide problem.

As illustrated in FIGS. 11-12, Nickel Silicide layer 1016 in open areas is essentially the same as Nickel Silicide thickness 1014 in active areas in accordance with one embodiment of the invention.

Accordingly, a need exists to provide methods for fabricating an integrated circuit having a Nickel Silicide layer which is substantially devoid of holes in both the active regions and in the open regions of the device. Additionally, it is desirable to provide MOSFET transistors having a continuous Silicide layer in the presence of SiGe. A further need exists to provide IC devices and methods for fabricating IC devices having a Silicide layer which is free of voids in the vicinity of high aspect ratio (AR) structures and which is of uniform thickness across the device surface.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the invention in any way. Rather, the foregoing detailed description will provide those skilled in the art with a convenient road map for implementing the exemplary embodiments. Various changes can be made in the size, spacing and doping of elements without departing from the scope of the invention as set forth in the appended claims and the legal equivalents thereof.

What is claimed is:

1. A method for fabricating an integrated circuit device on a silicon substrate having an active region and an open region, comprising:
depositing a layer of metal over said open region and said active region;
transferring at least a portion of said layer of metal into the respective surfaces of said open region and said active region to produce a Silicide layer in said active and said open regions;
controlling the depth of penetration of said Silicide layer to a uniform thickness by exposing said substrate to a predetermined elevated temperature for a predetermined period of time, leaving some excess metal on the surface of at least said open region; and
removing said excess metal from said surface of said open region.

2. The method of claim 1 wherein depositing a layer of metal comprises depositing a layer of nickel.

3. The method of claim 1 further comprising:
patterning microelectronic structures in said active region prior to depositing said metal layer; and
wherein depositing said metal layer comprises depositing said metal layer on the top surfaces of said microelectronic structures.

4. The method of claim 3 wherein at least one of said microelectronic structures comprises a gate electrode.

5. The method of claim 4 wherein transferring comprises producing a homogeneous Nickel Silicide layer in said active and said open areas.

6. The method of claim 3 wherein patterning microelectronic structures comprises patterning high aspect ratio structures.

7. The method of claim 1 wherein depositing said metal layer comprises depositing a layer of nickel in a thickness range of about 200 A.

8. The method of claim 1 wherein depositing said metal layer comprises depositing nickel by chemical vapor deposition.

9. The method of claim 1 wherein depositing said metal layer comprises depositing nickel by plasma enhanced chemical vapor deposition.

10. The method of claim 2 wherein depositing said metal layer comprises depositing nickel by physical vapor deposition.

11. The method of claim 2 wherein said silicon substrate comprises SiGe.

12. The method of claim 11 wherein transferring comprises thermal migration of said nickel into said SiGe.

13. The method of claim 12 wherein said thermal migration process comprises rapid thermal annealing.

14. The method of claim 13 wherein said rapid thermal annealing comprises annealing said substrate for about 30 seconds at a temperature range of about 240 to 320 degrees Centigrade.

15. The method of claim 13 wherein said rapid thermal annealing step comprises annealing said semiconductor substrate at a temperature of about 300 degrees C.

16. The method of claim 15 wherein:
depositing said metal layer comprises depositing a layer of nickel in a thickness range of about 200 A; and
controlling comprises controlling the depth of penetration of said Nickel Silicide layer to a thickness in the range of about 100 A.

17. The method of claim 15 wherein controlling comprises producing a continuous, homogeneous Nickel Silicide layer of uniform thickness in the range of about 100 nm across said active and said open areas, said Nickel Silicide layer being substantially devoid of Spotty NiSi-type holes.

18. The method of claim 1 wherein removing comprises removing unreacted nickel from said open area.

19. A method for fabricating an IC device on a silicon substrate having an active region and an open region, comprising:
patterning microelectronic structures on said active region;
depositing a layer of nickel atoms at a thickness of about 200 A on said active and said open regions;
migrating said nickel atoms into the respective surfaces of said open region and said active region to produce a nickel Silicide layer;
controlling the depth of penetration of said nickel Silicide layer to a uniform thickness of about 100 A by annealing said substrate at about 300 C. for about 30 seconds;
leaving some unreacted nickel atoms on the surface of said open region; and
removing said unreacted nickel atoms from said surface of said open region.

20. A MOSFET device comprising:
a Silicon Germanium semiconductor substrate having an active region and an open region;
a plurality of gate electrodes having sidewalls defining isolation regions patterned on said active region; and
a nickel Silicide layer extending into said active and said open regions, including said isolation regions, to a uniform depth of penetration in the range of about 100 A;
wherein said Silicide layer is substantially homogeneous and is substantially free of Spotty NiSi-type holes.
